(19) United States
(12) Patent Application Publication
(10) Pub. No.: US 2003/0046633 A1
(43) Pub. Date: Mar. 6, 2003

(54) Data error correction based on reported factors and predicted data interference factors

(76) Inventor: Curtis E. Jutzi, Lake Oswego, OR (US)

Correspondence Address: BLAKELY SOKOLOFF TAYLOR & ZAFMAN, 12400 WILSHIRE BOULEVARD, SEVENTH FLOOR, LOS ANGELES, CA, 90025, US

(21) Appl. No.: 09/941,435

(22) Filed: Aug. 28, 2001

(51) Int. Cl. H03M 13/00

(52) U.S. Cl. 714/774

(57) ABSTRACT

In an aspect, a method and a system are provided to improve data transmission. In an aspect, the transmitted data is broadcasted. Data is compiled on reported factors that cause data transmission errors and predictions are compiled on unreported factors that cause data transmission errors. In an aspect, the data transmission error factors include regional factors including terrain, environmental factors including weather, atmospheric conditions, sunspot activity and season, radio frequency propagation including Keplerian elements, and retransmission factors. In an aspect, data error correction is employed based on the reported factors and on the predicted factors.

### FIELD

This invention relates to transmitting data, more particularly, an apparatus and method that improves data transmission reliability by compiling reported interference factors and predicting unreported interference factors used for error correction of data transmission.

### BACKGROUND

In the deployment of large scale content broadcasting, poor or unsatisfactory data reception caused by interference factors in the path of the transmitting data between a transmitter and a receiver is a usual issue. This concern is applicable to both analog and digital signals, including the digital television transmission (DTV) formats such as the recently available high definition television (HDTV) and standard definition television (SDTV) having technical standards established by the American Television Systems Committee (ATSC), an international organization.

Broadcast systems traditionally transmit data in one direction from a server system to a plurality of client systems. Consumers of the client systems typically receive the signals from the server system as they are broadcast. Currently, error correction practices are utilized that increase the reliability of the reception of transmitted data including forward error correction (FEC) techniques and carouselling (retransmission of the same data), convolutional (tree) codes and block codes. FEC, however, is not useful with analog communications because the degradation of analog signals cannot be effectively corrected. Often these various error correction techniques are employed to handle transmission errors but show unsatisfactory results since there are often a myriad of data transmission interference factors. Some interference factors are regional such as terrain existing along the path of the data transmission, and other factors are dynamic based on environmental factors including weather and season. Retransmission factors are a further consideration such that data can be transmitted to many locations, each having different regional and dynamic factors. For example, satellite communications systems use orbiting satellites as radio repeaters to relay signals between earth stations. Most telecommunications satellites in use today are in geostationary orbit about 22,300 miles above the equator. Satellite systems can be used for one-way, two-way, point-to-point or point-to-multipoint transmission of various types of signals, including voice, data and video. Further, interference can occur in the up-link transmission from earth station to satellite, or in the down-link from satellite to earth.

### BRIEF DESCRIPTION OF THE DRAWINGS

Additional advantages of the invention will become apparent upon reading the following detailed description and upon reference to the drawings, in which:

FIG. 1 is a representation of a content provider, a broadcast center server, an error correction engine, a reported factors sources, and a receiving client, in an embodiment of the invention;

FIG. 2 depicts a partial listing of regional factors, dynamic factors and retransmission factors that can cause data transmission interference;

FIG. 3 is a diagram depicting Error Correction Engine functions, in an embodiment of the invention;

FIG. 4 depicts an error factor algorithm used for error correction by an Error Correction Engine, in an embodiment of the invention; and

FIG. 5 is a method diagram depicting Error Correction Engine methods and transmitter methods, in an embodiment of the invention.

### DETAILED DESCRIPTION

Exemplary embodiments are described with reference to specific configurations. Those of ordinary skill in the art will appreciate that various changes and modifications can be made while remaining within the scope of the appended claims. Additionally, well-known elements, devices, components, circuits, process steps and the like are not set forth in detail in order to avoid obscuring the present invention.

Currently, there is a need for control and optimization of bandwidth and Quality of Service (QOS) of a given broadcast based on regional factors including terrain, and transient conditions including weather that effect the level of service to the end client (i.e. the receiver). Information exists, and is readily available, on surrounding or nearby regional factors and transient conditions where broadcasting occurs. Often the information is updated, current and reliable. QOS is currently a significant concern for continuous transmission of high-bandwidth video and multimedia information.

In an embodiment, the invention provides error correction of data transmission in communications, for data transmission interference caused by regional factors including terrain, dynamic factors including weather and season, and retransmission factors. In an embodiment, a method and system is provided that controls Quality of Service (QOS), a guaranteed and specified networking throughput level. Transmission rates, error rates and other characteristics are improved, and to some extent guaranteed in advance. In an embodiment, the reliability of data transmission is increased (for both analog and digital data transmission) between a transmitter and a receiver, as compared to currently used systems.

In an embodiment, information available through outside sources (e.g., the National Weather Service) is utilized for error correction of regional factors and transient conditions that are spatially within a path of data transmission, nearby a path of data transmission, or that pose an interference factor to data transmission. Further, predictions are made and compiled on unreported factors that can cause data transmission errors. In an embodiment, reported factors and unreported factors that cause data transmission errors are compiled and utilized for error correction. In an embodiment, only the compiled reported factors and predictions are utilized and required for error correction.

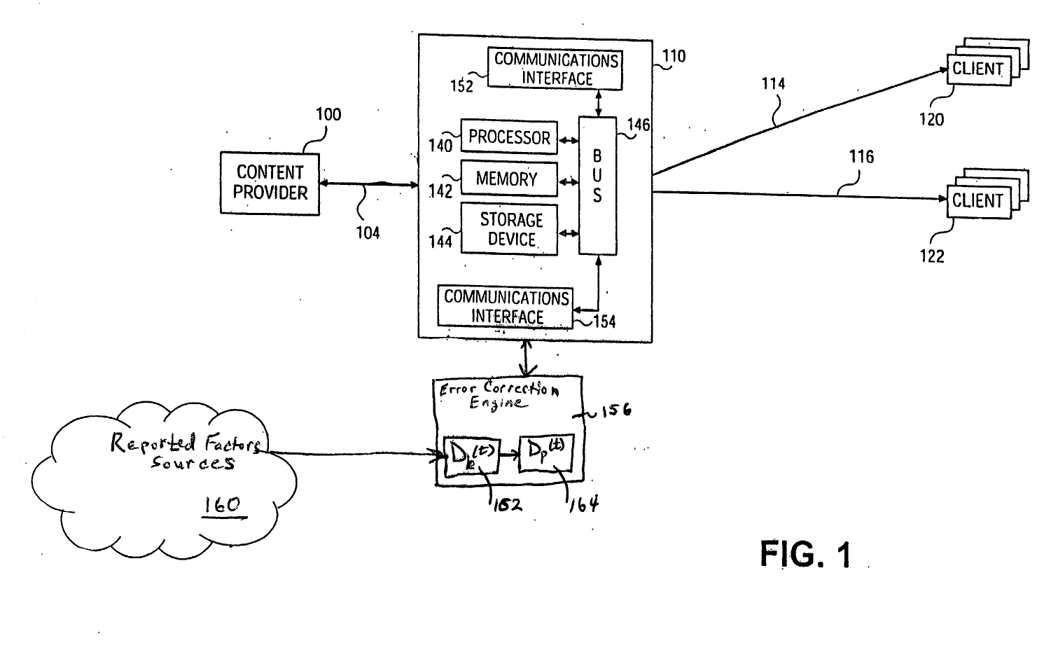

FIG. 1 is a representation of a content provider, a broadcast center server, an error correction engine, a source of reported factors that cause data transmission interference, and a receiving client, in an embodiment of the invention. In an embodiment, at least one content provider 100 provides a product to a broadcast center server 110. Content provider 100 provides the product in at least one of an analog and a digital format. In an embodiment, content provider 100 hand delivers the product via physical tape to broadcast center server 110. Content provider 100 can be a server computer, a group, a subnetwork, a local area network (LAN) or other group of multiple computers. The product can be a television program, movie, short, raw data, voice, audio, video, graphics, common data, or some combination of these or other similar data. In an embodiment, content provider 100 provides the product via connection 104. In an embodiment, connection 104 is a land line such as T1 lines, T3 lines, coaxial cable, Ethernet, twisted-pair, fiber optic such as a Synchronous Optical Network (SONET), or other physically present connection. In another embodiment, connection 104 is wireless in the form of microwave, satellite, radio waves, and the like. Yet in another embodiment, connection 104 is a hand delivery of a product such as a physical tape delivered via a common carrier including the U.S. Postal Service or commercial carriers such as UPS or Federal Express.

In an embodiment, broadcast center server 110 receives the product from content provider 100 via connection 104. In an embodiment, broadcast center server 110 is a server computer or a group of computers including a subnetwork, cluster or a LAN. Broadcast center server 110 distributes the product to consumers such as clients 120 and 122.

In an embodiment, broadcast center server 110 utilizes Asynchronous Transfer Mode (ATM) to transfer data in cells or packets of a fixed size. In an embodiment, the ATM creates a fixed channel between broadcast center server 110 and clients 120 and 122 when the transfer of data begins. In another embodiment, each packet is transmitted individually and can follow different routes to its destination. After receiving the packets, clients 120 and 122 recompile the packets into the original message. In an embodiment, by utilizing ATM, high-speed (up to 2.5 gigabits) switching service capable of carrying voice, data, video and multimedia images is provided. This allows ATM providers to guarantee to their customers that end-to-end latency will not exceed a specified level.

In an embodiment, the products sent to the clients are sent in a digital format. In an embodiment, broadcast center server 110 is comprised of one or more server computers that include a processor 140, a memory 142 such as any Random Access Memory (RAM) device, a storage device 144 to store data received from the content providers and clients, and at least one communications interface 152. In an embodiment, multiple communications interfaces 152 and 154 are utilized for communication with content providers as already described, and for communication with clients as will be described below. Storage device 144 can be any machine readable medium including hard disk drives, optical disk drives, magnetic tape, etc.

Software implementing the methods described herein can be stored on storage device 144 or other machine readable medium included in broadcast center server 110, including magnetic and optical disks; magnetic tape; read-only memory (ROM), programmable read-only memory (PROM), electronically erasable programmable memory (EEPROM), and similar semiconductor devices; or can be downloaded from any external or remote device via electrical, acoustical, or other form of propagated signal (e.g., carrier waves, digital signals, infrared signals, etc.).

In an embodiment, processor 140, memory 142, storage device 144, and communications interfaces 152 and 154 are coupled via bus 146. In an embodiment, broadcast center server 110 includes multiple or additional communications interfaces, processors, storage devices, display adapters, and buses. In an embodiment, broadcast center server 110 includes multiple server computers that can be dedicated communications servers, applications servers, storage servers, and other specialized servers configured as a LAN, group, subgroup, cluster, subnetwork, and the like.

In an embodiment, clients 120 and 122 that receive products are a computing device such as a set-top box, personal computer, portable computer, cellular telephone, personal digital assistant (PDA), computing tablet, or any other device containing a processor with a communications interface that allows for the receipt of data distributed via connections 114 and 116. In an embodiment, the set-top box utilizes a TCP/IP communications stack. In an embodiment, the set-top box is attached to a service through a telephone line or through a cable TV company. In an embodiment, the set-top box contains one or more processors for running the operating system, and for parsing the MPEG standards transport stream. In an embodiment, the set-top box includes RAM, an MPEG decoder chip, and more chips for audio decoding and processing. The set-top box can also be DVB-compliant to decode COFDM transmissions or ATSC-compliant to decode VSB transmissions.

In an embodiment, clients 120 and 122 receive broadcast products wirelessly via a conventional ground terrestrial transmission, via a digital television (DTV) connection 114, via satellite connection 116 and via a wide area network (WAN) connection. The WAN can be the Internet. In another embodiment, clients 120 and 122 receive broadcast product via cable television (CATV) connection. In an embodiment, a CATV connection is a WAN. The DTV connection display formats is one of High Definition Television (HDTV) and Standard Definition Television (SDTV). In an embodiment, clients 120 and 122 receive 8-level vestigial sideband (8-VSB) format chosen by the ATSC for the broadcast of DTV.

In an embodiment, error correction engine 156 compiles data on reported factors, from reported factors sources 160, that cause data transmission errors. In an embodiment, error correction engine 156 is within broadcast center server 110. Reported factors sources 160 includes all available sources of information providing regional factors and transient conditions that pose an interference factor to data transmission (e.g., the National Weather Service, the National Meteorological Agency, Doppler Radar). Error correction engine 156 selectively retrieves and compiles reported factor data that poses an interference factor spatially within a path of data transmission, nearby a path of data transmission, and directly to a particular data transmission. The reported factor data is compiled in reported data device 162. In an embodiment, error correction engine 156 further makes predictions on unreported factors that can cause data transmission errors. The predictions are compiled and utilized for error correction on data to be transmitted. The predictions on unreported factors is made and compiled in prediction data device 164. In an embodiment, prediction data device 164 utilizes data from reported data device 162 to make predictions. In an embodiment, reported factors and predicted unreported factors that cause data transmission errors are utilized for error correction on data to be transmitted. In an embodiment, error correction engine 156 employs error correction on data to be transmitted. In an embodiment, only the compiled reported factors and predictions are utilized and required for error correction on data to be transmitted. That is, in an embodiment, no data transmission error reporting from clients 120 and 122 is utilized by error correction engine 156.

In an embodiment, compiling data on the reported factors and on the unreported factors includes collecting data that can effect data transmission on a path to at least one receiver such as clients 120 and 122, and collecting data on at least one of regional data, environmental data, atmospheric data, sunspot activity and season, radio frequency propagation data, and retransmission factors. In an embodiment the regional data includes terrain, the environmental data includes weather data, and the radio frequency propagation data includes Keplerian data. In an embodiment, the compiling data on reported factors includes at least one of continuously collecting data and collecting data at predetermined events that can effect data transmission. In an embodiment, predicting unreported factors includes at least one of continuously predicting and predicting at predetermined events that can effect data transmission. In an embodiment, employing error correction includes dynamically employing at least one of forward error correction and carouselling, and adjusting at least one of bandwidth and Quality Of Service (QOS). In an embodiment, transmitting by broadcast center server 110 includes broadcasting data.

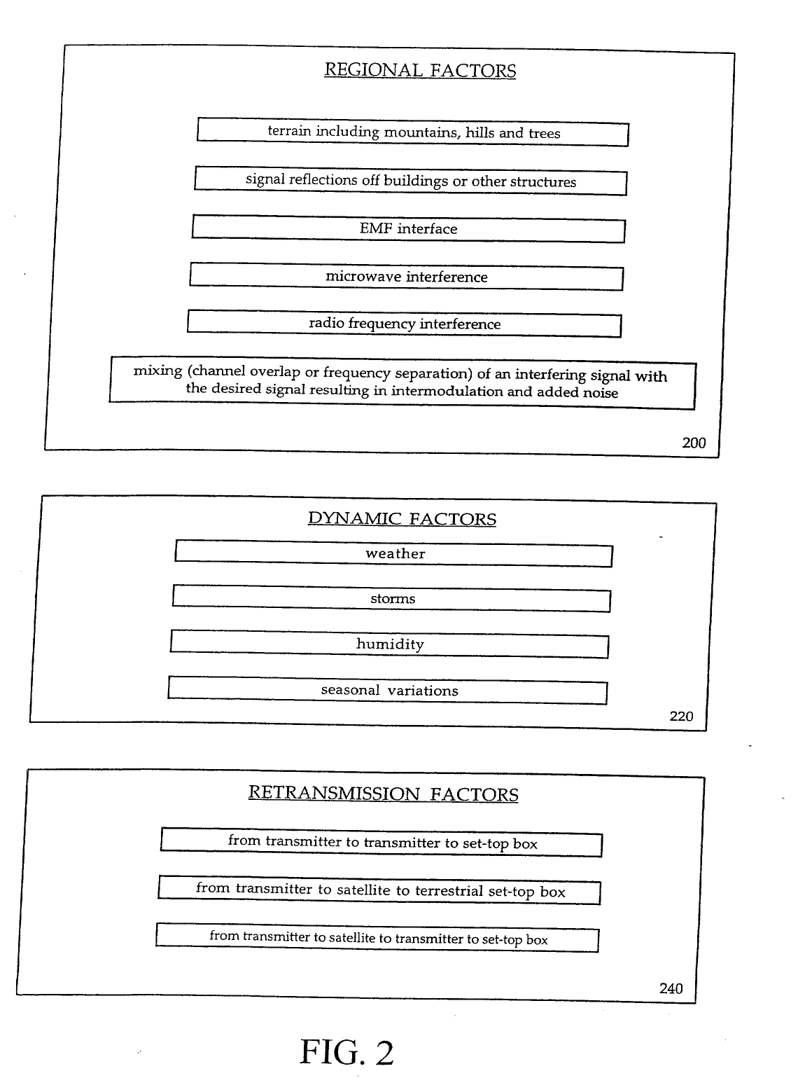

FIG. 2 depicts a partial listing of regional factors, dynamic factors and retransmission factors that can cause transmission interference. Transmission interference can be caused during transmission between broadcast center server 110 and one of clients 120 and 122 while utilizing one of digital television connection 114 and satellite connection 116. As presented in block 200, the regional factors comprise terrain including mountains, hills and trees. Other regional factors include signal reflections off buildings or other structures, EMF interference, microwave interference, radio frequency interference and mixing (channel overlap or frequency separation) of an interfering signal with the desired signal resulting in intermodulation and added noise. As presented in block 220, the dynamic factors include weather, storms, humidity and seasonal variations. As presented in block 240, the retransmission factors include transmission from transmitter to transmitter to set-top box, transmission from transmitter to satellite to terrestrial set-top box, and transmission from transmitter to satellite to transmitter to set-top box.

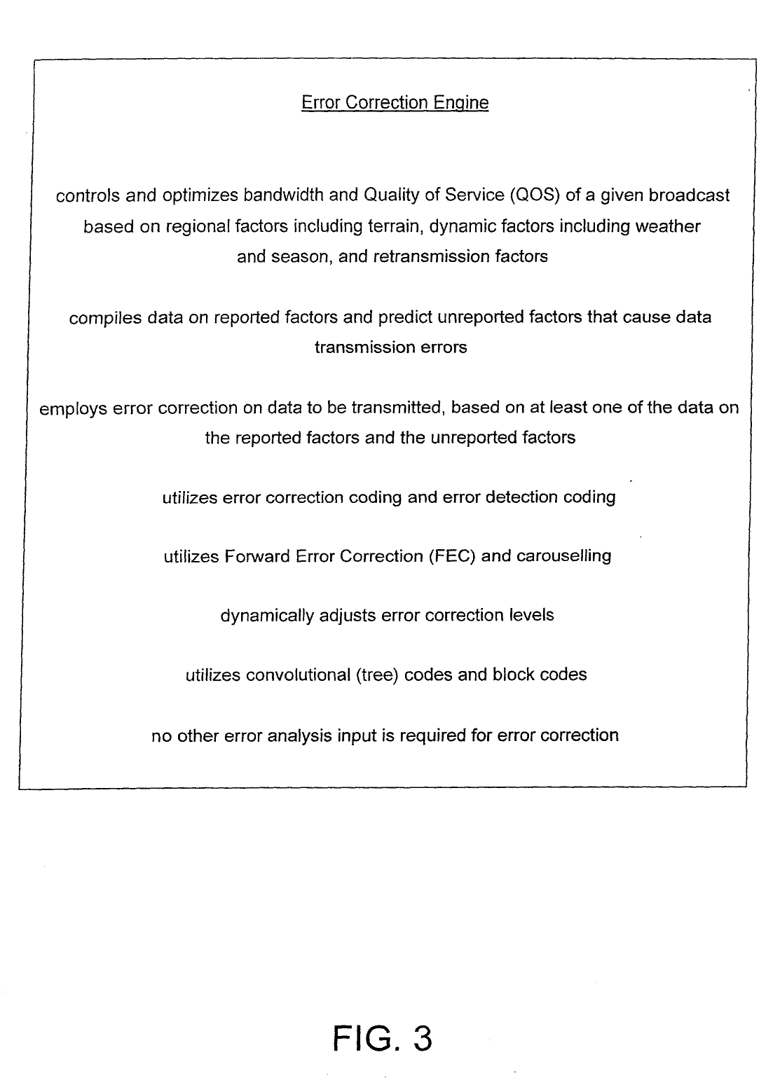

In an embodiment, broadcast center server 110 includes error correction engine 156. In an embodiment, error correction engine 156 is wirelessly connected to and separate from, broadcast center server 110. When the appended claims refer to “a transmitter, coupled to the error correction engine” it is intended that a variety of couplings can be employed such as a wireless coupling. In an embodiment, the functions of error correction engine 156 are shown in FIG. 3. In an embodiment, error correction engine 156 decreases the transmitted data error level by adjusting error correction of transmitted data. In an embodiment, error correction engine 156 controls and optimizes bandwidth and Quality of Service (QOS) of a given broadcast based on regional factors, dynamic factors, and retransmission factors. In an embodiment, error correction engine 156 compiles data on reported factors and predicts unreported factors that cause data transmission errors. In an embodiment, error correction engine 156 employs error correction on data to be transmitted, based on at least one of the data on the reported factors and the unreported factors. In an embodiment, error correction of transmitted data is applied dynamically. By dynamically adjusting a level of error correction it is meant that the adjusting is applied in response to changes in dynamic factors including weather, rather than at designated intervals of, for example, every hour. In an embodiment, at least one of error correction coding and error detection coding is utilized. In an embodiment, error correction engine 156 utilizes at least one of convolutional (tree) codes and block codes. In an embodiment, broadcast center server 110 includes processor 140 that executes a decoding algorithm to decode convolutional codes. By error correcting the data transmission in an embodiment of the invention, bandwidth is increased, the amount of data that is transmitted in a fixed amount of time, since the effects of regional factors and dynamic factors are reduced. In an embodiment, error correction engine 156 utilizes Forward Error Correction (FEC) and adds check bits to the data stream, thereby increasing the transmission reliability. Clients 120 and 122 analyze the check bit information to locate and correct errors. In an embodiment, error correction engine 156 utilizes carouselling.

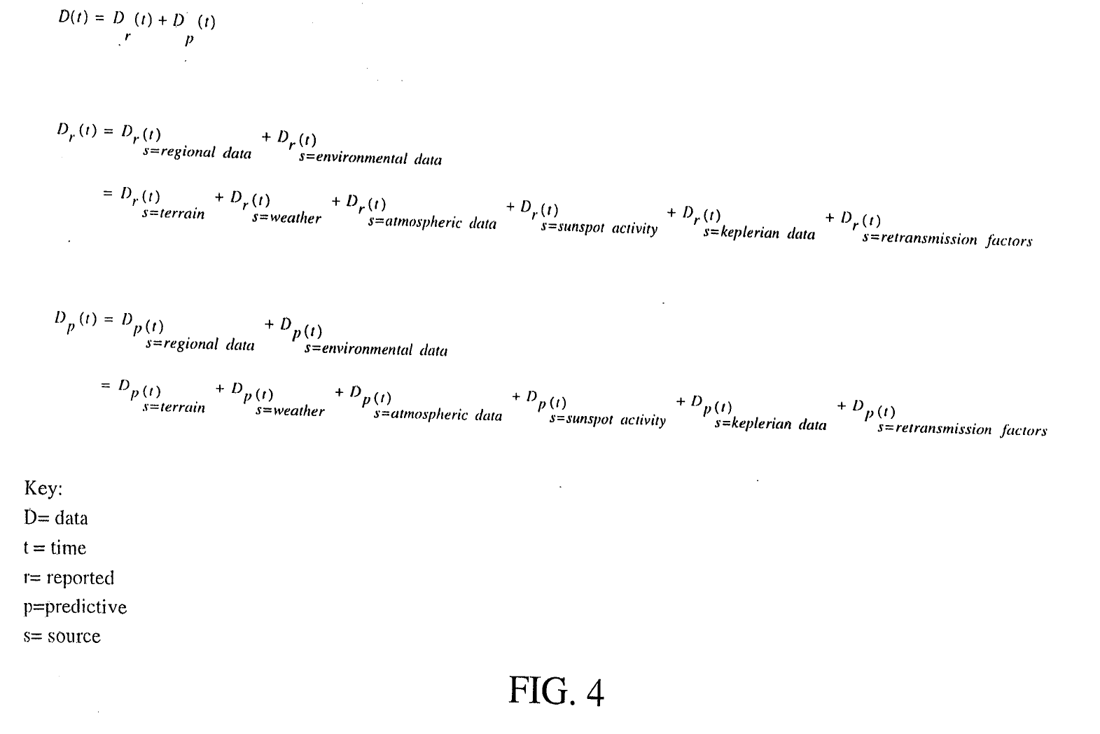

FIG. 4 depicts an error factor algorithm utilized for error correction by error correction engine 156, in an embodiment of the invention. In an embodiment, error correction engine 156 compiles data on reported interference factors and predicted interference factors. The interference factors that effect data transmissions are represented as D(t). The D(t) factors include reported interference factors Dᵣ(t) and predicted interference factors Dₚ₍ₜ₎. The reported interference factors Dᵣ(t) include reported regional interference factors Dᵣ_{^{(t)}}_{_{regional}} and reported environmental interference factors Drᵣ_{^{(t)}}_{ₛ₌ₑₙᵥᵢᵣₒₙₘₑₙₜₐₗ}. The reported interference factors Dr (t) can be further described to be equal to Dᵣ_{^{(t)}}_{ₛ₌ₜₑᵣᵣₐᵢₙ}+Dᵣ_{^{(t)}}_{_{s=weather}}+Dᵣ_{^{(t)}}_{_{s=atmospheric data}}+Dᵣ_{^{(t)}}_{_{s=sunspot activity}}+Dᵣ_{^{(t)}}_{_{s=keplerian data}}+Dᵣ_{^{(t)}}_{_{s=retransmission factors}}. The predicted interference factors Dₚ(t) include predicted regional interference factors Dₚ_{^{(t)}}_{_{s=regional}} and predicted environmental interference factors Dₚ_{^{(t)}}_{ₛ₌ₑₙᵥᵢᵣₒₙₘₑₙₜₐₗ}. The predicted interference factors Dₚ(t) can be further described to be equal to Dₚ_{^{(t)}}_{ₛ₌ₜₑᵣᵣₐᵢₙ}+Dₚ_{^{(t)}}_{_{s=weather}}+Dₚ_{^{(t)}}_{_{s=atmospheric data}}+Dₚ_{^{(t)}}_{_{s=sunspot activity}}+Dₚ_{^{(t)}}_{_{s=keplerian data}}+Dₚ_{^{(t)}}_{_{s=retransmission factors}}.

In an embodiment, error correction engine 156 calculates the chance and likelihood that reported interference factors Dᵣ(t) and predicted interference factors Dₚ (t) will effect data transmission. Once calculated, error correction engine 156 utilizes the calculated chance and likelihood in applying error correction on data to be transmitted. Further, error correction engine 156 calculates the potential impact and effect that the reported interference factors Dᵣ(t) and predicted interference factors Dₚ (t) can have on the data transmission. Once calculated, error correction engine 156 utilizes the calculated potential impact and effect in applying error correction on data to be transmitted.

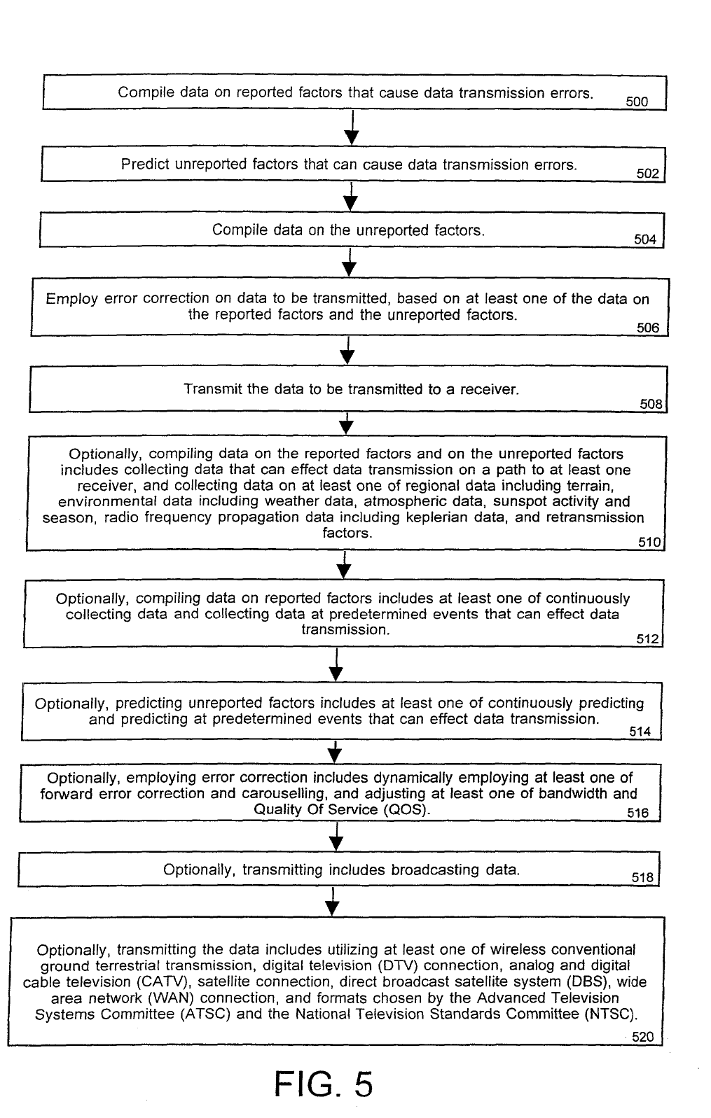

FIG. 5 is a method diagram depicting methods of error correction engine 156, and a transmitter, in an embodiment of the invention. In an embodiment, as shown in method blocks 500-508, error correction engine 156 compiles data on reported factors that cause data transmission errors, predicts and compiles data on unreported factors that can cause data transmission errors, and employs error correction on data to be transmitted, based on at least one of the data on the reported factors and the unreported factors. The data is then transmitted to a receiver.

In an embodiment, as shown in method block 510, compiling data on the reported factors and on the unreported factors includes collecting data that can effect data transmission on a path to at least one receiver, and collecting data on at least one of regional data including terrain, environmental data including weather data, atmospheric data, sunspot activity and season, radio frequency propagation data including Keplerian data, and retransmission factors. In an embodiment, as shown in method block 512, the compiling data on reported factors includes at least one of continuously collecting data and collecting data at predetermined events that can effect data transmission. In an embodiment, as shown in method block 514, predicting unreported factors includes at least one of continuously predicting and predicting at predetermined events that can effect data transmission. In an embodiment, as shown in method block 516, employing error correction includes dynamically employing at least one of forward error correction and carouselling, and adjusting at least one of bandwidth and Quality Of Service (QOS). In an embodiment, as shown in method block 518, transmitting includes broadcasting data. In an embodiment, as shown in method block 520, transmitting the data includes utilizing at least one of wireless conventional ground terrestrial transmission, digital television (DTV) connection, analog and digital cable television (CATV), satellite connection, direct broadcast satellite system (DBS), wide area network (WAN) connection, and formats chosen by the Advanced Television Systems Committee (ATSC) and the National Television Standards Committee (NTSC).

An embodiment of the invention provides a machine readable medium having instructions that when executed by a processor cause the processor to perform operations. In an embodiment, the operations include at least one of the methods as discussed herein with reference to FIG. 4. In an embodiment, the methods as discussed herein with reference to FIG. 4 are embodied in machine-executable instructions. The instructions can be used to cause a general-purpose or special-purpose processor that is programmed with the instructions to perform the methods of an embodiment of the invention. Alternatively, the methods of an embodiment of the invention can be performed by specific hardware components that contain hardwired logic, or by any combination of programmed computer components and custom hardware components.

The machine-readable storage medium includes any mechanism that provides (i.e., stores and/or transmits) information in a form readable by a machine (e.g., a computer). For example, a machine-readable medium includes floppy diskettes, optical disks, compact disc, Read-Only Memory (CD-ROMs), and magneto-optical disks, Read-Only Memory (ROMs), Random Access Memory (RAMs), Erasable Programmable Read-Only Memory (EPROMs), Electrically Erasable Read-Only Memory (EEPROMs), magnetic disk storage media, optical storage media, flash memory devices, electrical, optical, acoustical or other form of propagated signals (e.g., carrier waves, infrared signals, digital signals, etc.), and other type of media/machine-readable medium suitable for storing electronic instructions, etc.

Having disclosed exemplary embodiments and the best mode, modifications and variations can be made to the disclosed embodiments while remaining within the spirit and scope of the invention as defined by the appended claims.

What is claimed is:

1. A method comprising:
compiling data on reported factors that cause data transmission errors;
predicting unreported factors that can cause data transmission errors;
compiling data on the unreported factors;
employing error correction on data to be transmitted, based on at least one of the data on the reported factors and the unreported factors; and
transmitting the data to be transmitted to at least one receiver.

2. The method as in claim 1, wherein the compiling data on the reported factors and on the unreported factors comprises collecting data that can effect data transmission on a path to the at least one receiver, and collecting data on at least one of regional data, environmental data, atmospheric data, sunspot activity and season, radio frequency propagation data, and retransmission factors.

3. The method as in claim 1, wherein the compiling data on reported factors comprises at least one of continuously collecting data and collecting data at predetermined events that can effect data transmission.

4. The method as in claim 1, wherein the predicting unreported factors comprises at least one of continuously predicting and predicting at predetermined events that can effect data transmission.

5. The method as in claim 1, wherein the employing error correction comprises employing at least one of forward error correction and carouselling, and adjusting at least one of bandwidth and Quality Of Service (QOS).

6. The method as in claim 1, wherein the employing error correction comprises dynamically adjusting error correction.

7. The method as in claim 1, wherein the transmitting comprises broadcasting data.

8. The method of claim 1, wherein the transmitting the data comprises utilizing at least one of wireless conventional ground terrestrial transmission, digital television (DTV) connection, analog and digital cable television (CATV), satellite connection, direct broadcast satellite system (DBS), wide area network (WAN) connection, and formats chosen by the Advanced Television Systems Committee (ATSC) and the National Television Standards Committee (NTSC).

9. An apparatus comprising:
an error correction engine to compile data on reported factors that cause data transmission errors, predict and compile unreported factors that can cause data transmission errors, and employ error correction on data to be transmitted, based on at least one of the data on the reported factors and the unreported factors; and
a transmitter, coupled to the error correction engine, to transmit the data to be transmitted to at least one receiver.

10. The apparatus as in claim 9, wherein the error correction engine collects data that can effect data transmission on a path to the at least one receiver, and collects data on at least one of regional data, environmental data, atmospheric data, sunspot activity and season, radio frequency propagation data, and retransmission factors.

11. The apparatus as in claim 9, wherein the error correction engine at least one of continuously collects data on reported factors and collects data on reported factors at predetermined events that can effect data transmission.

12. The apparatus as in claim 9, wherein the error correction engine at least one of continuously predicts unreported factors and predicts unreported factors at predetermined events that can effect data transmission.

13. The apparatus as in claim 9, wherein the transmitter broadcasts data.

14. The apparatus as in claim 9, wherein the error correction engine dynamically employs at least one of forward error correction and carouselling, and adjusts at least one of bandwidth and Quality Of Service (QOS).

15. The apparatus of claim 9, wherein the transmitter utilizes at least one of wireless conventional ground terrestrial transmission, digital television (DTV) connection, analog and digital cable television (CATV), satellite connection, direct broadcast satellite system (DBS), wide area network (WAN) connection, and formats chosen by the Advanced Television Systems Committee (ATSC) and the National Television Standards Committee (NTSC).

16. A machine readable medium having instructions that when executed by a processor cause the processor to perform operations comprising:
compiling data on reported factors that cause data transmission errors;
predicting unreported factors that can cause data transmission errors;
compiling data on the unreported factors;
employing error correction on data to be transmitted, based on at least one of the data on the reported factors and the unreported factors; and
transmitting the data to be transmitted to at least one receiver.

17. The machine readable medium of claim 16, wherein the compiling data on the reported factors and on the unreported factors comprises collecting data that can effect data transmission on a path to the at least one receiver, and collecting data on at least one of regional data, environmental data, atmospheric data, sunspot activity and season, radio frequency propagation data, and retransmission factors.

18. The machine readable medium of claim 16, wherein the compiling data on reported factors comprises at least one of continuously collecting data and collecting data at predetermined events that can effect data transmission.

19. The machine readable medium of claim 16, wherein the predicting unreported factors comprises at least one of continuously predicting and predicting at predetermined events that can effect data transmission.

20. The machine readable medium of claim 16, wherein the employing error correction comprises employing at least one of forward error correction and carouselling, and adjusting at least one of bandwidth and Quality Of Service (QOS).

21. The machine readable medium of claim 16, wherein the employing error correction comprises dynamically adjusting error correction.

22. The machine readable medium of claim 16, wherein the transmitting comprises broadcasting data.

23. The machine readable medium of claim 16, wherein the transmitting the data comprises utilizing at least one of wireless conventional ground terrestrial transmission, digital television (DTV) connection, analog and digital cable television (CATV), satellite connection, direct broadcast satellite system (DBS), wide area network (WAN) connection, and formats chosen by the Advanced Television Systems Committee (ATSC) and the National Television Standards Committee (NTSC).
